(19) United States
(12) Patent Application Publication
(10) Pub. No.: US 2025/0344596 A1
(43) Pub. Date: Nov. 6, 2025

(54) DISPLAY DEVICE WITH ULTRAVIOLET PROTECTION

(71) Applicant: SAMSUNG DISPLAY CO., LTD., YONGIN-SI (KR)

(72) Inventor: Jong Hwan CHO, Yongin-si (KR)

(21) Appl. No.: 19/081,024

(22) Filed: Mar. 17, 2025

(30) Foreign Application Priority Data
May 2, 2024 (KR) 10-2024-0058728

(51) Int. Cl. H10K 59/80; C08K 5/23; C08K 5/315; C08K 5/3475; G02B 1/14; H10K 102/00

(52) U.S. Cl. CPC H10K 59/8792; C08K 5/23; C08K 5/315; C08K 5/3475; G02B 1/14; H10K 59/879; H10K 2102/311

(57) ABSTRACT

According to an embodiment of the present invention, a display device includes: a substrate; a display layer disposed on the substrate; a film layer disposed on the display layer; a hard coating layer disposed on the film layer; and a low refractive index layer disposed on the hard coating layer, wherein the film layer includes an ultraviolet absorber.

### CROSS-REFERENCE TO RELATED APPLICATION

This application claims priority under 35 U.S.C. § 119 to Korean Patent Application No. 10-2024-0058728 filed in the Korean Intellectual Property Office on May 2, 2024, the disclosure of which is incorporated by reference herein in its entirety.

### TECHNICAL FIELD

Embodiments of the present invention relate to a display device, and more particularly, to a display device with ultraviolet protection.

### DISCUSSION OF THE RELATED ART

Generally, display devices include, for example, liquid crystal displays and organic light emitting displays.

Unlike liquid crystal displays, which require a backlight unit, organic light emitting displays generate light independently, eliminating the need for a backlight. This self-emissive property allows for a display panel to have a reduced thickness, so recent research has focused on flexible, stretchable, foldable, bendable, or rollable organic light emitting displays.

Generally, a flexible display device includes a flexible window that is disposed on a display panel that displays an image, thereby protecting the display device and ensuring flexibility.

### SUMMARY

According to an embodiment of the present invention, a display device includes: a substrate; a display layer disposed on the substrate; a film layer disposed on the display layer; a hard coating layer disposed on the film layer; and a low refractive index layer disposed on the hard coating layer, wherein the film layer includes an ultraviolet absorber.

In an embodiment of the present invention, the low refractive index layer includes dodecafluoroheptyl acrylate.

In an embodiment of the present invention, the ultraviolet absorber includes at least one of an azomethine-based compound, cyanoacrylate, or benzotriazole.

In an embodiment of the present invention, the low refractive index layer has a thickness between about 80 nm and about 120 nm.

In an embodiment of the present invention, the film layer includes polyethylene terephthalate.

In an embodiment of the present invention, the ultraviolet absorber includes a mixture of an azomethine-based compound and benzotriazole in a ratio of about 0.8 to about 1.2 for the azomethine-based compound to about 2 to about 3 for the benzotriazole.

In an embodiment of the present invention, the film layer includes a mixture of the polyethylene terephthalate, and the mixture of an azomethine-based compound and benzotriazole in the ratio of about 0.8 to about 1.2 for the azomethine-based compound to about 2 to about 3 for the benzotriazole.

In an embodiment of the present invention, the ultraviolet absorber includes a mixture of an azomethine-based compound and cyanoacrylate in a ratio of about 0.8 to about 1.2 for the azomethine-based compound to about 1.6 to about 2.4 for the cyanoacrylate.

In an embodiment of the present invention, the film layer includes polyethylene terephthalate, the film layer includes a mixture of the polyethylene terephthalate, and mixture of an azomethine-based compound and cyanoacrylate in a ratio of about 0.8 to about 1.2 for the azomethine-based compound to about 1.6 to about 2.4 for the cyanoacrylate.

According to an embodiment of the present invention, a display device includes: a substrate; a display layer disposed on the substrate; a film layer disposed on the display layer; a hard coating layer disposed on the film layer; and a low refractive index layer disposed on the film layer, wherein the low refractive index layer includes an ultraviolet absorber.

In an embodiment of the present invention, the low refractive index layer has a thickness between about 80 nm and about 120 nm.

In an embodiment of the present invention, the film layer has a thickness between about 40 μm and about 90 μm, and the hard coating layer has a thickness between about 3 μm and 7 about μm.

In an embodiment of the present invention, the low refractive index layer includes random silsesquioxane monomers to which 12 perfluorinated groups and 6 reactive groups are attached.

In an embodiment of the present invention, each of the 12 perfluorinated groups is selected from at least one of C3F7, C3F9, C4F9, or C5F11.

In an embodiment of the present invention, the ultraviolet absorber includes at least one compound of an azomethine-based compound, cyanoacrylate, or benzotriazole.

In an embodiment of the present invention, the film layer includes polyethylene terephthalate.

In an embodiment of the present invention, the ultraviolet absorber includes a mixture of an azomethine-based compound and cyanoacrylate in a ratio of about 0.8 to about 1.2 for the azomethine-based compound to about 1.6 to about 2.4 for the cyanoacrylate.

In an embodiment of the present invention, the display device further includes a mixture of silsesquioxane monomers and the ultraviolet absorber in a ratio of about 5.4 to about 9.6 for the silsesquioxane monomers to about 1.6 to about 2.4 for the ultraviolet absorber.

In an embodiment of the present invention, the ultraviolet absorber includes a mixture of an azomethine-based compound and benzotriazole in a ratio of about 0.8 to about 1.2 for the azomethine-based compound to about 2 to about 3 for the benzotriazole.

In an embodiment of the present invention, a mixture of the silsesquioxane monomers and the ultraviolet absorber in a ratio of about 5.4 to about 9.6 for the silsesquioxane monomers to about 1.6 to about 2.4 for the ultraviolet absorber.

According to an embodiment of the present invention, an electronic device includes: a display device; and a power supply configured to provide power to the display device, wherein the display device includes: a substrate; a display layer disposed on the substrate; a film layer disposed on the display layer; a hard coating layer disposed on the film layer; and a low refractive index layer disposed on the hard coating layer, wherein the film layer or the low refractive index layer includes an ultraviolet absorber.

In an embodiment of the present invention, the ultraviolet absorber includes at least one of an azomethine-based compound, cyanoacrylate, or benzotriazole.

In an embodiment of the present invention, the electronic device further includes a thin film encapsulation layer disposed on the display layer.

In an embodiment of the present invention, the low refractive index layer has a thickness between about 80 nm and about 120 nm.

In an embodiment of the present invention, the film layer includes polyethylene terephthalate.

In an embodiment of the present invention, the ultraviolet absorber includes a mixture of an azomethine-based compound and benzotriazole in a ratio of about 0.8 to about 1.2 for the azomethine-based compound to about 2 to about 3 for the benzotriazole.

### BRIEF DESCRIPTION OF THE DRAWINGS

FIG. 1 is a schematic perspective view illustrating a display device according to an embodiment of the present invention.

FIG. 2 is an exploded perspective view of a display device according to an embodiment of the present invention.

FIG. 3 is a perspective view schematically illustrating a display device according to an embodiment of the present invention.

FIG. 4 is a schematic cross-sectional view of a portion of a display device according to an embodiment of the present invention.

FIG. 5 is a schematic cross-sectional view of a portion of a display device according to an embodiment of the present invention.

FIG. 6 is a schematic cross-sectional view of a portion of a display device according to a comparative example.

FIG. 7 is a schematic cross-sectional view of a portion of a display device according to a comparative example.

FIG. 8 is a schematic cross-sectional view of a portion of a display device according to a comparative example different from that of FIG. 7.

FIG. 9 schematically illustrates a manufacturing process of a film layer and a hard coating layer of a display device, according to an embodiment of the present invention.

FIG. 10 illustrates a manufacturing process of a low refractive index layer of a display panel shown in FIG. 4, according to an embodiment of the present invention.

FIG. 11 illustrates a manufacturing process of a low refractive index layer of a display panel shown in FIG. 5, according to an embodiment of the present invention.

FIG. 12 is a graph showing the results of the transmission spectral spectrum of the display panel shown in FIG. 4.

FIG. 13 is a graph showing the results of the reflection spectral spectrum of the display panel shown in FIG. 4.

FIG. 14 is a graph showing the results of ultraviolet spectroscopy and visible spectroscopy of the display panel shown in FIG. 5.

FIG. 15 is a graph showing the results of surface analysis of the display panel shown in FIG. 5 through X-ray photoelectron spectroscopy.

FIG. 16 is a block diagram illustrating an electronic device according to an embodiment of the present invention.

### DETAILED DESCRIPTION OF THE EMBODIMENTS

The present invention will be described in detail hereinafter with reference to the accompanying drawings. As those skilled in the art would realize, the described embodiments of the present invention may be modified in various different ways, without departing from the spirit or scope of the present invention.

The drawings and description are to be regarded as illustrative in nature and not restrictive. Like reference numerals designate like elements throughout the specification and drawings.

In the drawings, various thicknesses, lengths, and angles are shown and while the arrangement shown does indeed represent an embodiment of the present invention, it is to be understood that modifications of the various thicknesses, lengths, and angles may be possible within the spirit and scope of the present invention and the present invention is not necessarily limited to the particular thicknesses, lengths, and angles shown.

It will be understood that when an element such as a layer, film, region, or substrate is referred to as being “on” another element, it can be directly on the other element or intervening elements may also be present therebetween. In contrast, when an element is referred to as being “directly on” another element, there are no intervening elements present. Further, when an element is referred to as being “on” or “above” a reference element, it can be disposed above or below the reference element, and it is not necessarily referred to as being disposed “on” or “above” in a direction opposite to gravity.

“About” or “approximately” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” can mean within one or more standard deviations, or within ±30%, 20%, 10% or 5% of the stated value.

In addition, the phrase “on a plane” means a view from a position above the object (e.g., from the top), and the phrase “on a cross-section” means a view of a cross-section of the object which is vertically cut from the side.

Embodiments of the present invention relate to a display device that includes materials to increase durability, flexibility, and resistance to ultraviolet (UV) rays. It is particularly suited for flexible display technologies such as foldable, bendable, and rollable displays, making it applicable to portable devices such as smartphones, smartwatches, and automotive displays.

The display device may include a multilayer structure including of a substrate, a display layer, a film layer with an ultraviolet (UV) absorber, a hard coating layer, and a low refractive index layer. The UV absorber in the film layer may prevent damage to the light-emitting elements caused by UV radiation, thereby increasing the durability and stability of the display device. This may help in maintaining the optical properties and functionality of the display device over time, especially under prolonged exposure to light.

To further increase optical performance, the low refractive index layer may include compounds such as dodecafluoroheptyl acrylate, which may help reduce reflection and increase visibility. The combination of materials may ensure effective UV blocking, high transparency, and scratch resistance, while the hard coating layer adds mechanical strength to withstand physical impacts.

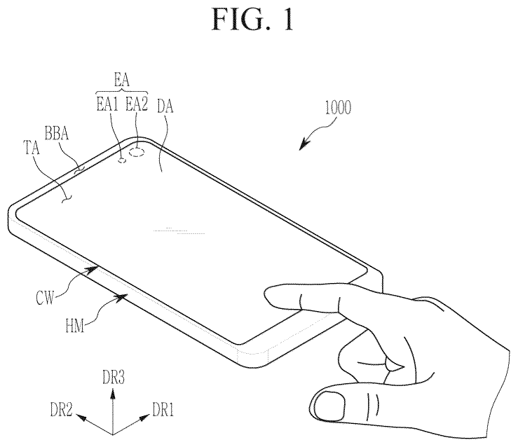

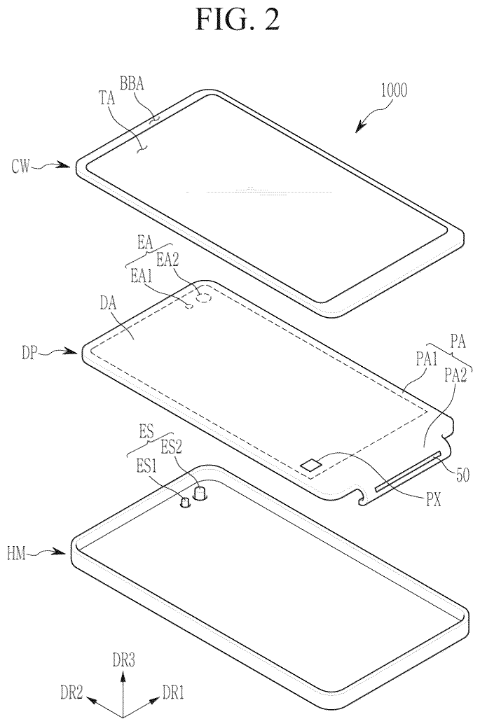

Hereinafter, a schematic structure of a display device will be described with reference to FIGS. 1 and 2.

FIG. 1 is a schematic perspective view illustrating a use state of a display device according to an embodiment of the present invention, and FIG. 2 is an exploded perspective view of a display device according to an embodiment of the present invention.

Referring to FIG. 1, a display device 1000 according to an embodiment of the present invention in represents a device for displaying moving images or still images, and it may be used as a display screen for portable electronic devices such as mobile phones, smartphones, tablet personal computers (PC), mobile communication terminals, electronic organizers, electronic books, portable multimedia players (PMP), global positioning systems, or ultra mobile PCs (UMPC), and also for various products such as televisions, laptops, monitors, advertisement boards, or internet of things (IOT). In addition, the display device 1000 according to an embodiment of the present invention may also be used to wearable devices such as smart watches, watch phones, glass-type displays, or head mounted displays (“HMD”). In addition, the display device 1000 according to an embodiment of the present invention may be used as a dashboard of a vehicle, a center information display (CID) disposed on a center fascia or a dashboard of a vehicle, a room mirror display replacing a side-view mirror of a vehicle, and a display disposed on a rear surface of a front seat for entertainment for a back seat of a vehicle. As an example, FIG. 1 illustrates the display device 1000 being used as a smart phone for convenience of description.

The display device 1000 may display images in a third direction DR3 from a displaying surface in parallel to a first direction DR1 and a second direction DR2. The displaying surface for displaying images may correspond to a front surface of the display device 1000, and may correspond to a front surface of a cover window CW. The images may include videos, moving images, and still images.

In an embodiment of the present invention, front surfaces (or upper surfaces) and rear surfaces (or lower surfaces) of respective members are defined with reference to the image displaying direction. The front surface and the rear surface may oppose each other in the third direction DR3, and normal-line directions of the front surface and the rear surface may be parallel to the third direction DR3. A spaced distance between the front surface and the rear surface in the third direction DR3 may correspond to a thickness of a respective member in the third direction DR3.

The display device 1000 according to an embodiment of the present invention may sense a user input (refer to the hand in FIG. 1) that is applied from the outside. The user input may include various types of external inputs such as some of a human body of the user, light, heat, or pressures. In an embodiment of the present invention, the user input is shown as being the user's hand being applied to the front surface. However, the present invention is not limited thereto. The user input may be provided in various forms, and the display device 1000 may also sense the user input that is applied to the side surface or rear surface of the display device 1000 depending on the structure of the display device 1000.

Referring to FIGS. 1 and 2, the display device 1000 may include the cover window CW, a housing HM, the display panel DP, and an optical element ES. In an embodiment of the present invention, the cover window CW and the housing HM may be combined to configure the exterior of the display device 1000.

The cover window CW may include an insulating panel. For example, the cover window CW may be made of glass, plastic, or a combination thereof.

The front surface of the cover window CW may correspond to and provide the front surface of the display device 1000. A transmission area TA may be an optically transparent area. For example, the transmission area TA may be an area with visible ray transmittance of about 90% or more.

A blocking area BBA may define the shape of the transmission area TA. The blocking area BBA may be adjacent to the transmission area TA and at least partially surround the transmission area TA. The blocking area BBA may be an area with relatively low light transmittance compared to the transmission area TA.

The display panel DP may include a display pixel PX, which is for displaying an image, and a driver 50, and the display pixel PX is disposed in a display area DA and a component area EA. The display panel DP may include a front surface including the display area DA and a non-display area PA. In an embodiment of the present invention, the display area DA and the component area EA may be areas where an image is displayed by pixels, and at the same time, may be areas where a touch sensor is disposed above the pixels in the third direction DR3 to sense an external input.

The transmission area TA of the cover window CW may at least partially overlap the display area DA and the component area EA of the display panel DP. For example, the transmission area TA may overlap the front surface of the display area DA and the component area EA, or may at least partially overlap the display area DA and the component area EA. Accordingly, the user may view the image through the transmission area TA or provide external input based on the image. However, the present of the present invention is not limited thereto. For example, the area where an image is displayed and the area where external input is sensed may be separated from each other.

The non-display area PA of the display panel DP may at least partially overlap the blocking area BBA of the cover window CW. The non-display area PA may be an area covered by the blocking area BBA. The non-display area PA may be adjacent to the display area DA and may at least partially surround the display area DA. An image is not displayed in the non-display area PA, and a driving circuit or driving wiring for driving the display area DA may be disposed in the non-display area PA. The non-display area PA may include a first non-display area PA1, which is disposed outside the display area DA, and a second non-display area PA2, which includes the driver 50, connection wiring, and a bending area. In the embodiment of the present invention, the first non-display area PA1 is disposed on three side of the display area DA, and the second non-display area PA2 is disposed on the remaining one side of the display area DA.

Part of the non-display area PA of the display panel DP may be curved. At this time, part of the non-display area PA may face the rear surface of the display device 1000, thereby reducing the size of the blocking area BBA that is visible on the front surface of the display device 1000, and in FIG. 2, the second non-display area PA2 may be bent and disposed on the rear surface of the display area DA and then assembled.

Additionally, the component area EA of the display panel DP may include a first component area EA1 and a second component area EA2. The first component area EA1 and the second component area EA2 may be at least partially surrounded by the display area DA. The first component area EA1 and the second component area EA2 are shown to be spaced apart from each other, but the present invention is not limited thereto and may be at least partially connected to each other. The first component area EA1 and the second component area EA2 may be areas in which an optical element (see ES in FIG. 2; hereinafter referred to as a component) that uses infrared rays, visible rays, or sounds is disposed.

The display area DA (hereinafter also referred to as a main display area) and the component area EA are formed with a plurality of light emitting diodes and a plurality of pixel circuits that generate and transmit electrical current to each of the plurality of light emitting diodes, enabling them to produce light. Here, one light emitting diode and one pixel circuit are called a pixel PX. One pixel circuit and one light emitting diode may be formed one-to-one in the display area DA and the component area EA.

The first component area EA1 may include a display layer including a plurality of pixels and a transmission part that may transmit light and/or sound. The transmission part is disposed between adjacent pixels and includes a layer that may transmit light and/or sound. The transmission part may be disposed between adjacent pixels, and depending on the embodiment, a layer that does not transmit light, such as a light blocking member, may overlap the first component area EA1. The number of pixels per unit area (hereinafter referred to as resolution) of the pixels included in the display area DA (hereinafter referred to as normal pixels) may be the same as the number of pixels per unit area of the pixels included in the first component area EA1 (hereinafter referred to as first component pixels).

The second component area EA2 includes an area including a transparent layer to transmit light (hereinafter also referred to as a light-transmitting area). The light-transmitting area may have a structure in which the conductive layer or semiconductor layer is not disposed and does not block light by including a layer that includes a light blocking material, for example, a pixel-defining layer and/or a light blocking member, with openings that overlap with positions corresponding to the second component area EA2. The number of pixels per unit area of the pixels included in the second component area EA2 (hereinafter referred to as second component pixels) may be smaller than the number of pixels per unit area of the normal pixels included in the display area DA. As a result, the resolution of the second component area EA2 may be lower than the resolution of the display area DA.

The second non-display area PA2 may include a bending part. The display area DA and the first non-display area PA1 may have a flat state substantially parallel to the plane defined by the first direction DR1 and the second direction DR2, and one side of the second non-display area PA2 may be extended from a flat state, pass through the bending part, and then be in a flat state again. For example, the second non-display area PA2 may include a portion that is bent such that it overlaps a lower surface of the display panel DP. As a result, at least a portion of the second non-display area PA2 may be bent and assembled to be disposed on the rear surface of the display area DA. When assembled, at least a portion of the second non-display area PA2 may overlap on a plane with the display area DA, thereby reducing the blocking area BBA of the display device 1000.

The driver 50 may be mounted on the second non-display area PA2, and may be mounted on the bending part or disposed on one of both sides of the bending part. The driver 50 may be provided in the form of a chip.

The driver 50 may be electrically connected to the display area DA and the component area EA to transmit electrical signals to pixels in the display area DA and the component area EA. For example, the driver 50 may provide data signals to the pixels PX arranged in the display area DA. In addition, the driver 50 may include a touch driving circuit and may be electrically connected to a touch sensor disposed in the display area DA and/or the component area EA. In addition, the driver 50 may include various circuits in addition to the above-described circuits or may be designed to provide various electrical signals to the display area DA.

In addition, a pad part may be disposed at an end of the second non-display area PA2 of the display device 1000, and the display device 1000 may be connected to a flexible printed circuit board (FPCB) including a driving chip through the pad part.

Here, the driving chip disposed on the FPCB may include various driving circuits for driving the display device 1000 and/or a connector for power supply. Depending on the embodiment, a rigid printed circuit board (PCB) may be used instead of the FPCB.

The optical element ES may be disposed below the display panel DP. The optical element ES may include a first optical element ES1, which overlaps the first component area EA1, and a second optical element ES2, which overlaps the second component area EA2. The first optical element ES1 may use infrared rays, and in this case, a layer that does not transmit light, such as a light blocking member, may overlap the first component area EA1.

The first optical element ES1 may be an electronic element that uses light or sound. For example, the first optical element ES1 may be a sensor configured to receive and use light, such as an infrared sensor. In addition, as an example, the first optical element ES1 may be a sensor that is configured to measure a distance or recognize a fingerprint by outputting and detecting light or sound, a small lamp configured to output light, a speaker configured to output sound, or the like. When the first optical element ES1 is an electronic element using light, the first optical element ES1 may use light of various wavelengths, such as visible light, infrared light, and/or ultraviolet light.

The second optical element ES2 may be at least one of a camera, an IR camera, a dot projector, an IR illuminator, or a time-of-flight sensor (ToF sensor).

The housing HM may be combined with the cover window CW. The cover window CW may be disposed on the front surface of the housing HM. The housing HM may be combined with the cover window CW to provide a predetermined accommodation space therebetween. The display panel DP and the optical element ES may be accommodated in a predetermined accommodation space provided between the housing HM and the cover window CW.

The housing HM may include a material with a relatively high rigidity. For example, the housing HM may include a plurality of frames and/or plates made of glass, plastic, or metal, or a combination thereof.

The housing HM may stably protect the components of the display device 1000 that are accommodated in the internal space, of the housing HM, from external impact.

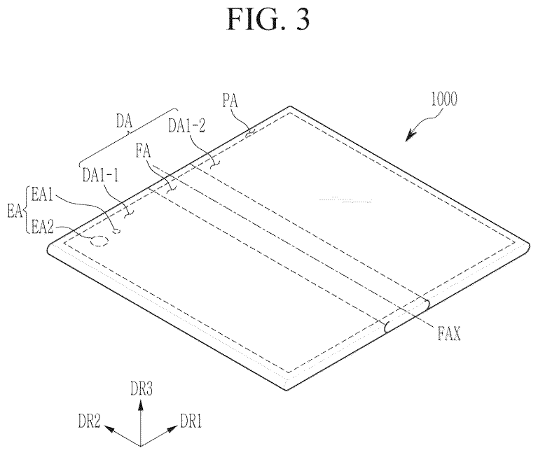

Hereinafter, the structure of the display device 1000 according to an embodiment of the present invention will be described with reference to FIG. 3. FIG. 3 is a perspective view schematically illustrating a light emitting display device according to an embodiment of the present invention. Descriptions of the same components as those described above will be omitted, and the embodiment of FIG. 3 shows a foldable display device in which the display device 1000 is folded through a folding axis FAX.

Referring to FIG. 3, in an embodiment of the present invention, the display device 1000 may be a foldable display device. The display device 1000 may be folded outward or inward with reference to the folding axis FAX. When the display device 1000 is folded outward with reference to the folding axis FAX, the display surfaces of the display device 1000 are disposed on the outside in the third direction DR3 so that images may be displayed in both directions. When the display device 1000 is folded inward with reference to the folding axis FAX, the display surface is not visible from the outside.

In an embodiment of the present invention, the display device 1000 may include the display area DA, the component area EA, and the non-display area PA. The display area DA may be divided into a 1-1 display area DA1-1, a 1-2 display area DA1-2, and a folding area FA. The 1-1 display area DA1-1 and the 1-2 display area DA1-2 may be disposed on the left and right sides, respectively, with reference to (or centered on) the folding axis FAX, and the folding area FA may be disposed between the 1-1 display area DA1-1 and the 1-2 display area DA1-2. At this time, when folded outward with reference to the folding axis FAX, the 1-1 display area DA1-1 and the 1-2 display area DA1-2 are disposed on both sides in the third direction DR3, and the image may be displayed in both directions. For example, when folded outward, the 1-1 display area DA1-1 and the 1-2 display area DA1-2 may face opposite directions, with respect to each other. Additionally, when folded inward with reference to the folding axis FAX, the 1-1 display area DA1-1 and the 1-2 display area DA1-2 are not visible from the outside. For example, when folded inward with reference to the folding axis FAX, the 1-1 display area DA1-1 and the 1-2 display area DA1-2 may face each other.

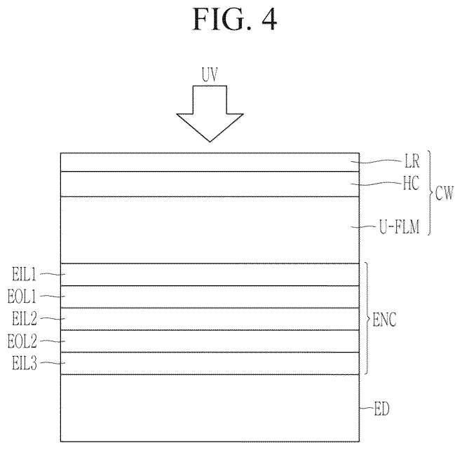

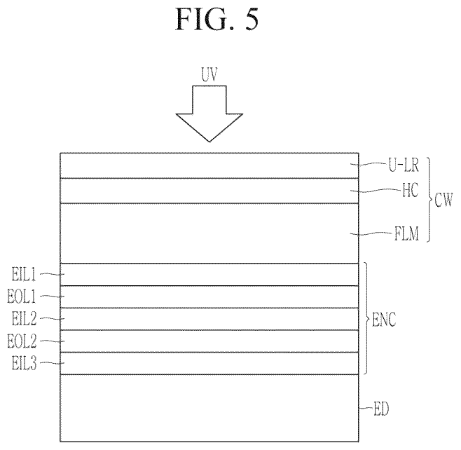

Hereinafter, the window structure of the display device, according to an embodiment of the present invention will be described with reference to FIGS. 4 and 5. FIG. 4 is a schematic cross-sectional view of a portion of a display device according to an embodiment of the present invention, and FIG. 5 is a schematic cross-sectional view of a portion of a display device according to an embodiment of the present invention.

First, with reference to FIG. 4, a display device including a film layer including an ultraviolet absorber U-FLM will be described.

A display device according to an embodiment of the present invention may include a substrate, a display layer ED disposed on the substrate, a thin film encapsulation layer ENC disposed on a display layer ED, and the cover window CW disposed on top of the thin film encapsulation layer ENC.

The substrate may be a transparent substrate and may be made of a flexible material such as a polymer film.

The display layer ED may be disposed on the substrate. The display layer ED include an element area, where an optical element such as a thin film transistor (TFT) is formed, and a light emitting area, where a light emitting layer is formed. The element area and the light emitting area may be disposed either separately or overlapped with each other.

The thin film encapsulation layer ENC may be disposed on the display layer ED. The thin film encapsulation layer ENC may include a composite film that includes both an inorganic film and an organic film. In an embodiment of the present invention, the thin film encapsulation layer ENC comprises a structure in which a third inorganic encapsulation layer EIL3, a second organic encapsulation layer EOL2, a second inorganic encapsulation layer EIL2, a first organic encapsulation layer EOL1, and a first inorganic encapsulation layer EIL1 are sequentially disposed on the display layer ED. At least one of the inorganic encapsulation layer or the organic encapsulation layer described above may be omitted.

The thin film encapsulation layer ENC may be integrally provided to overlap the front surface of the display area, and may also be partially disposed on the non-display area. The display area may be protected from external air or moisture through the thin film encapsulation layer ENC.

The cover window CW is disposed on top of the thin film encapsulation layer ENC. The cover window CW may include a single member or a plurality of members. An embodiment of the present invention may include a plurality of window members, which may include a film layer, which includes an ultraviolet absorber U-FLM, a hard coating layer HC disposed on the film layer that includes the ultraviolet absorber U-FLM, and a low refractive index layer LR disposed on the hard coating layer HC. The window members serve to protect the cover window CW against scratches.

However, the structure of the cover window CW is not necessarily limited thereto, and may include other structures or may further include a protective film as a lower surface.

Hereinafter, the film layer including the ultraviolet absorber U-FLM included in the cover window CW will be described. Below, the film and the ultraviolet absorber included in the film layer including the ultraviolet absorber U-FLM will be described, respectively.

The film layer including the ultraviolet absorber U-FLM includes a film including a transparent material. The film may include, for example, glass or plastic. When including a film made of plastic, the cover window CW may have flexible properties. The plastic applied to the film may have excellent transparency, mechanical strength, thermal stability, moisture shielding, and isotropy. Examples of applicable plastics may include, but are not particularly limited to, polyethylene terephthalate (PET), polyacrylate, polyethylene naphthalate (PEN), poly(methyl methacrylate) (PMMA), polyurethane (PU), polyimide (PI), polycarbonate (PC), polyvinylidene chloride, polyvinylidene difluoride (PVDF), polystyrene, an ethylene vinyl alcohol copolymer, polyethersulfone (PES), polyetherimide (PEI), polyphenylene sulfide (PPS), polyallylate, tri-acetyl cellulose (TAC), cellulose acetate propionate (CAP), etc. The film layer including the ultraviolet absorber U-FLM may include one or more of the aforementioned plastic materials.

The cover window CW according to an embodiment of the present invention includes the film layer including the ultraviolet absorber U-FLM. The film layer including the ultraviolet absorber U-FLM includes polyethylene terephthalate (PET) represented by Chemical structure 1.

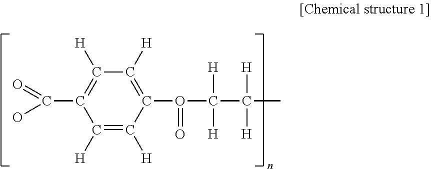

The thickness of the film layer including the ultraviolet absorber U-FLM may range from about 40 μm to about 90 μm.

The ultraviolet absorber U-FLM included in the film layer according to an embodiment of the present invention particularly serves to block ultraviolet A (UVA), which is a long wave with a wavelength of 315 nm to 400 nm. In particular, the ultraviolet absorber U-FLM serve to maintain the light transmittance in the ultraviolet region at a wavelength of about 370 nm to 0% or less. Through this, it is possible to increase the durability and stability of the display layer ED by suppressing or preventing the deterioration of optical elements included in the display layer ED due to ultraviolet rays.

The materials applied to the ultraviolet absorbers U-FLM are not particularly limited, but may include, for example, ultraviolet absorbers having various types of skeletal structures, such as benzotriazole compounds, cyanoacrylate compounds, triazine compounds, benzophenone compounds, triazine compounds, benzoxazinone compounds, salicylic acid compounds, and benzoxazine compounds, and combinations of one type or two or more types of these types. When two or more types of ultraviolet absorbers U-FLM are used together, the ultraviolet absorbers may have the same skeletal structure, or may have different skeletal structures from each other.

The film layer including ultraviolet absorber U-FLM may include a pigment that absorbs ultraviolet rays in addition to the ultraviolet absorber U-FLM. The pigment is not particularly limited, but may include, for example, pigments and dyes, which may be used alone or in combination.

The pigments may include, but are not specifically limited to, azomethine pigments such as copper azomethine yellow, phthalocyanine pigments such as phthalocyanine green, phthalocyanine blue, fast yellow, diazo yellow, condensed azo yellow, benzimidazolone yellow, dinitroaniline orange, benzamidazolone orange, toluidine red, permanent carmine, permanent red, naphthol red, condensed azo red, benzamidazolone carmine, benzamidazolone brown, azo-based pigments such as anthrapyrimidine yellow, anthraquinone pigments such as anthraquinolyl red, quinophthalone pigments such as quinophthalone yellow, isoindoline pigments such as isoindoline yellow, nitroso pigments such as nickel dioxime yellow, felinone pigments such as perinone orange, quinacridone magenta, quinacridone maroon, quinacridone crimson, quinacridone red, and quinacridone red, perylene-based pigments such as perylene red and perylene maroon, pyrrolopyrrole-based pigments such as diketopyrrolopyrrole red, dioxazine-based pigments such as dioxazine violet, carbon-based pigments such as carbon black, lamp black, furnace black, ivory black, graphite, and fullerene, chromate-based pigments such as yellow lead and molybdate orange, cadmium yellow, cadmium lithopone yellow, cadmium orange, cadmium lithopone orange, and silver vermilion, cadmium red, and cadmium lithopone red, sulfides such as sulfide, ochre, titanium yellow, titanium barium nickel yellow, an agglomerate, lead dan, amber, brown iron oxide, zinc iron chrome brown, chrome oxide, cobalt green, cobalt chrome green, titanium cobalt green, cobalt blue, cerulean blue, cobalt aluminum chrome blue, iron black, manganese ferrite black, cobalt ferrite black, copper chrome black, copper chrome manganese black, oxide-based pigments such as viridian, hydroxide-based pigments such as viridian, ferrocyanide-based pigments such as royal blue, silicate pigments such as ultramarine blue, phosphate pigments such as cobalt violet, mineral violet, and other inorganic pigments (for example, cadmium sulfide, cadmium selenide), and combinations of one type or two or more types of these types.

The ultraviolet absorber U-FLM included in the display device of an embodiment of the present invention may be a mixture of an azomethine-based compound represented by Chemical structure 2 and a benzotriazole represented by Chemical structure 3. The alkyl group of the azomethine-based compound may include a propyl group for R¹, an ethoxy group for R², and an alkoxycarbonyl group for R³. In an embodiment of the present invention, the ratio of the azomethine-based compound and benzotriazole may be about 0.8 to about 1.2 for the azomethine-based compound to about 2 to about 3 for the benzotriazole. In an experiment using the embodiment including an ultraviolet absorber U-FLM of the aforementioned ratio, the light transmittance in the ultraviolet region at about 370 nm was maintained at 0% or less, while the anti-reflection function of the low refractive index layer was maintained.

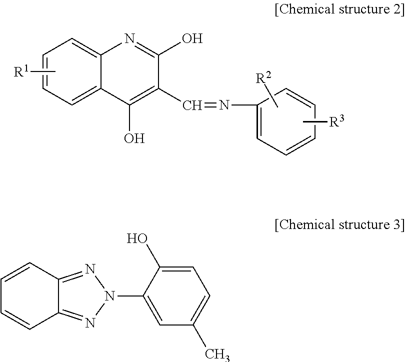

In an embodiment of the present invention, the ultraviolet absorber may include a mixture of an azomethine-based compound represented by Chemical structure 2 and a cyanoacrylate ultraviolet absorber represented by Chemical structure 4. In an embodiment of the present invention, the ratio of the azomethine-based compound to the cyanoacrylate may have ratio of about 0.8 to about 1.2 for the azomethine-based compound to about 1.6 to about 2.4 for the cyanoacrylate. In the embodiment including the ultraviolet absorber U-FLM in the aforementioned ratio, the film layer including the ultraviolet absorber U-FLM serves to block ultraviolet rays, while maintaining the anti-reflection function of the low refractive index layer.

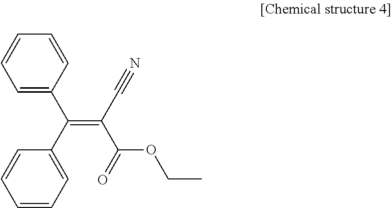 [SMILES: CCOC(=O)C(C#N)=C(c1ccccc1)c1ccccc1]

In an embodiment of the present invention, the ratio of the polyethylene terephthalate film to the ultraviolet absorber U-FLM may also be about 0.8 to about 1.2 for the polyethylene terephthalate film to about 1.2 to about 0.8 for the ultraviolet absorber U-FLM. This is the ratio to maintain the optical properties of the film layer.

The hard coating layer HC is disposed on the film layer including the ultraviolet absorber U-FLM to increase the hardness of the cover window CW.

In an embodiment of the present invention, the hard coating layer HC may include an organic layer and/or an organic-inorganic composite layer including an acrylate compound. For example, the organic layer may include an acrylate compound. The organic-inorganic composite layer may be a layer in which inorganic materials such as silicon oxide, zirconium oxide, aluminum oxide, tantalum oxide, niobium oxide, and glass beads are dispersed in an organic material such as an acrylate compound. In an embodiment of the present invention, the coating layer may include a metal oxide layer. The metal oxide layer may include metal oxides such as titanium, aluminum, molybdenum, tantalum, copper, indium, tin, and tungsten, but the present invention is not limited thereto.

The hard coating layer HC may have thickness between about 3 μm and about 7 μm.

The low refractive index layer LR is disposed on the hard coating layer HC. For example, the low refractive index layer LR may be disposed on a top surface of the hard coating layer HC. The low refractive index layer LR serves as an optical compensation layer and has an anti-reflection function. Even if the ultraviolet absorber U-FLM is included in the film layer including the ultraviolet absorber U-FLM, the anti-reflection function of the hard coating layer HC may be maintained.

Examples of the component including the low refractive index layer LR may include inorganic particles surface-treated with a fluorine compound (hereinafter referred to as fluorine-treated inorganic particles). For example, suitable inorganic particles for the fluorine-treated inorganic particles include inorganic particles including at least one of Si, Na, K, Ca, and/or Mg. An embodiment of the present invention includes inorganic particles including at least one of silica particles (SiO₂), alkali metal fluorides (NaF, KF, etc.) and alkaline earth metal fluorides (CaF₂, MgF₂, etc.), among which silica particles are particularly preferable considering durability, refractive index, and other factors.

Silica particles suitably used for the fluorine-treated inorganic particles are hollow silica particles (silica particles having cavities inside the particles) or porous silica particles (silica particles having pores on the surface and inside of the particles). For example, the silica particles may include, but are not limited thereto, a composition including silsesquioxane or a composition including silsesquioxane and a filler.

As methods for surface treating silica particles with a fluorine compound, it is preferable to use compounds such as dodecafluoroheptyl (meth) acrylate, 2,2,2-trifluoroethyl (meth) acrylate, 2,2,3,3,3-pentafluoropropyl (meth) acrylate, 2-perfluorobutyl ethyl (meth) acrylate, 3-perfluorobutyl-2-hydroxypropyl (meth) acrylate, 2-perfluorohexyl ethyl (meth) acrylate, 3-perfluorohexyl-2-hydroxypropyl (meth) acrylate, 2-perfluorooctyl ethyl (meth) acrylate, 3-perfluorooctyl-2-hydroxypropyl (meth) acrylate, 2-perfluorodecyl ethyl (meth) acrylate, 2-perfluoro-3-methylbutyl ethyl (meth) acrylate, 3-perfluoro-3-methoxybutyl-2-hydroxypropyl (meth) acrylate, 2-perfluoro-5-methylhexyl ethyl (meth) acrylate, 3-perfluoro-5-methylhexyl-2-hydroxypropyl (meth) acrylate, 2-perfluoro-7-methyl octyl-2-hydroxypropyl (meth) acrylate, tetrafluoropropyl (meth) acrylate, octafluoropentyl (meth) acrylate, hexadecafluorononyl (meth) acrylate, and hexafluorobutyl (meth) acrylate.

The low refractive index layer LR may have thickness between about 80 μm and about 120 μm.

In an embodiment of the present invention, the low refractive index layer LR includes dodecafluoroheptyl acrylate (DFHA) represented by Chemical structure 5.

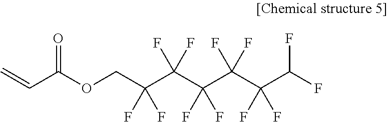 [SMILES: C=CC(=O)OCC(F)(F)C(F)(F)C(F)(F)C(F)(F)C(F)(F)C(F)F]

Referring to FIG. 5, a display device comprising a low refractive index layer including the ultraviolet absorber U-LR will be described, but description of the same components as those described above will be omitted.

The cover window CW of the embodiment of the present invention includes a film layer FLM that does not include an ultraviolet absorber. The film layer FLM may include a material such as a film included in the film layer including the ultraviolet absorber U-FLM of FIG. 4. In an embodiment of the present invention, the film layer FLM includes polyethylene terephthalate (PET) represented by Chemical structure 1.

The low refractive index layer including ultraviolet absorber U-LR may include random silsesquioxane monomers (Rf=9F-silsesquioxanetriol (CF₂CF₂CF₂CF₃), n=12) with 12 perfluoroalkyl and 6 reactive groups attached, as shown in Chemical structure 6. (Hereinafter referred to as R-type SQ.) Each of the 12 perfluoroalkyl of R-type SQ may include at least one of C₃F₇, C₃F₉, C₄F₉, and/or CsF₁₁.

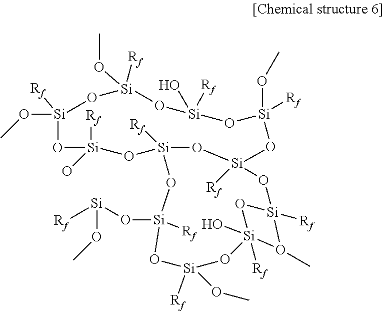

In an embodiment of the present invention, the ratio of the ultraviolet absorber U-LR and R-type SQ may be about 1.6 to about 2.4 for the ultraviolet absorber U-LR to about 5.4 to about 9.6 for the R-type SQ. In the embodiment including the aforementioned ratio of the ultraviolet absorber U-LR, the low refractive index layer including the ultraviolet absorber U-LR serves to block ultraviolet rays and have an anti-reflection function.

The low refractive index layer including the ultraviolet absorber U-LR may have a thickness between about 80 nm and about 120 nm. The efficiency and ultraviolet protection effect of the low refractive index layer including the ultraviolet absorber U-LR may be increased when the layer has a thickness of about 100 nm or more, because it is easier to control the ratio of the ultraviolet absorber to the R-type SQ, which is a component of the low refractive index layer including the ultraviolet absorber U-LR.

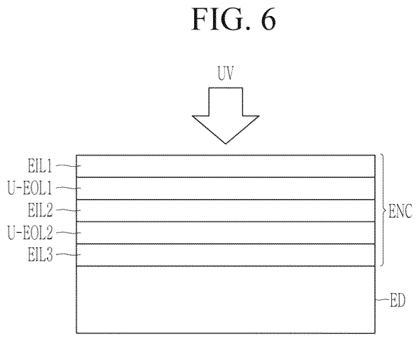

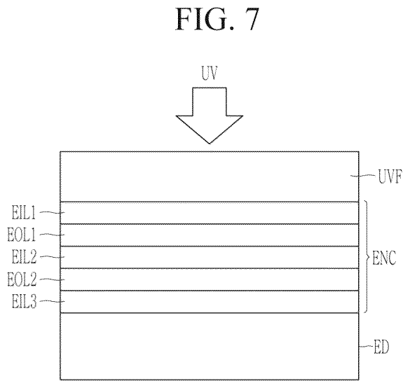

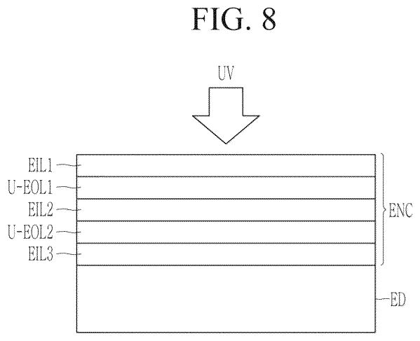

Hereinafter, the structure of the display device according to the comparative embodiment will be described through FIGS. 6 to 8. FIG. 6 is a schematic cross-sectional view of a portion of a display device according to a comparative example. FIG. 7 is a schematic cross-sectional view of a portion of a display device according to another comparative example, and FIG. 8 is a schematic cross-sectional view of a portion of a display device according to a comparative example that is different from that of FIG. 7.

The display panel of FIG. 6 does not include an ultraviolet absorber. Therefore, the display panel may be damaged by long-wavelength ultraviolet A that penetrate into the interior of the optical element.

The display panel of FIG. 7 has a structure including an ultraviolet blocking film UVF that is disposed on top of the thin film encapsulation layer ENC.

The ultraviolet blocking film UVF may include a material capable of absorbing ultraviolet, and may include, for example, benzophenone-based organic compounds, benzotriazole-based organic compounds, salicylate-based organic compounds, cyanoacrylate-based organic compounds, oxanilide-based organic compounds, resorcinol monobenzoate, and cinnamate.

When the ultraviolet blocking film UVF is disposed on the thin film encapsulation layer ENC, the thickness of the display panel is larger than that of the display panel according to an embodiment of the present invention, and the flexible display may have weakened foldability.

The display panel of FIG. 8 includes a material capable of absorbing ultraviolet in a dispersed form in an organic layer corresponding to the first organic encapsulation layer EOL1 and the second organic encapsulation layer EOL2 disposed in the thin film encapsulation layer ENC of FIG. 6. Accordingly, the thin film encapsulation layer ENC includes structures such as a first ultraviolet blocking organic encapsulation layer U-EOL1 and a second ultraviolet blocking organic encapsulation layer U-EOL2.

Ultraviolet absorbers included in the first ultraviolet blocking organic encapsulation layer U-EOL1 and the second ultraviolet blocking organic encapsulation layer U-EOL2 may include benzotriazole, benzophenone, and salicylate-based compounds.

However, in this case, the ultraviolet absorber may react with organic molecules in the thin film encapsulation layer ENC, and the encapsulation function of the thin film encapsulation layer ENC may be weakened when compared to an embodiment of the present invention.

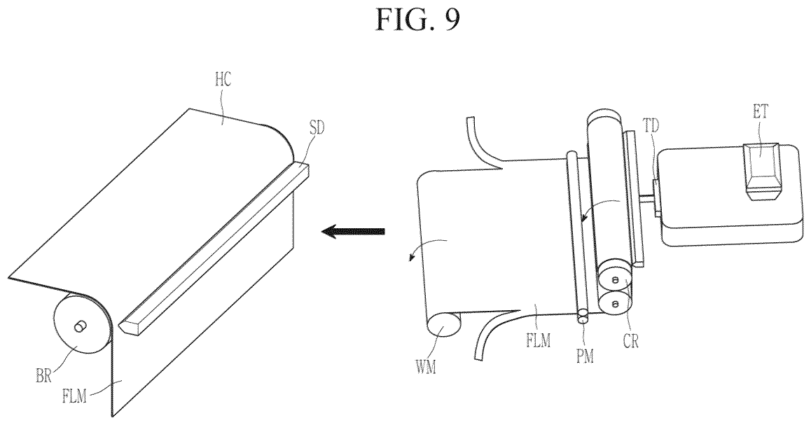

Hereinafter, with reference to FIGS. 9 to 15, embodiments of the present invention will be described in detail by comparing examples and comparative examples.

### Example 1

The manufacturing process of the film layer and hard coating layer will be described through FIG. 9. FIG. 9 schematically illustrates a manufacturing process of a film layer and a hard coating layer of a display device, according to an embodiment of the present invention.

The composition of the alkyl group of the azomethine-based compound represented by Chemical structure 2 used as an ultraviolet absorber is as follows. In Chemical structure 2, R¹ is propyl ([CH₃CH₂CH₂]ₙ, n=1), R² is ethoxy ([CH₃CH₂O]ₙ, n=6), and R³ is alkoxycarbonyl ([CH₃COO]ₙ, n=2).

The ultraviolet absorber is a mixture of azomethine-based compound and benzotriazole in a ratio of about 1 to about 2.5 (hereinafter referred to as an ultraviolet absorber 1.) The mixed ultraviolet absorber 1 is mixed with polyethylene terephthalate in a ratio of 1:1.

The mixed compound is put into an extruder ET, and then into a die casting TD machine to form a mold. After, the mixed compound is cooled using a cooling roll CR, and passed through a pick-up machine PM and winding machine WM to ensure that the film has a uniform thickness. For example, the pick-up machine PM and the winding machine WM may include rollers.

When the film is placed in the slot die coating SD equipment, a back roll BR rotates and the hard coating material is applied and dried.

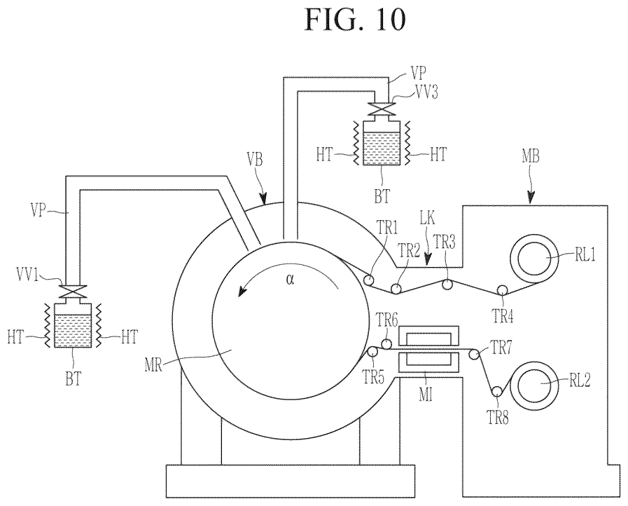

The manufacturing process of the low refractive index layer of the display panel will be described with reference to FIG. 10. FIG. 10 illustrates a manufacturing process of a low refractive index layer of a display panel shown in FIG. 4.

When the film with the hard coating layer stacked thereon is put into a first roll RL1 with a roll-on-roll process, a tension first roller TR1, a tension second roller TR2, a tension third roller TR3, and a tension fourth roller TR4 ensure that the film is evenly spread and put into a main roller MR. The film rotates at a constant angular speed a on the main roller MR.

When the film is rotationally put in, a first valve VV1 and a third valve VV3 are opened to allow the heated vaporizable material and the heated dodecafluoroheptyl acrylate n=8 monomer to be supplied into a vacuum bath VB in vapor form.

A microwave irradiation device MI is disposed at the end of the rotating part of the main roller MR. The film is put into the microwave irradiation device MI along a tension fifth roller TR5 and a tension sixth roller TR6. The microwave irradiation device MI generates plasma from the dodecafluoroheptyl acrylate n=8 monomer under the conditions of ion acceleration voltage of about 300 V and substrate temperature of about −20° C., causing sputtering on the film. The dodecafluoroheptyl acrylate n=8 monomer is deposited on the hard coating layer so that the film thickness is about 100 nm. After film formation, the film is discharged to the main body MB along a tension seventh roller TR7 and a tension eighth roller TR8.

### Example 2

Except for the following, all conditions are carried out in the same manner as in Example 1.

The ultraviolet absorber mixture of azomethine-based compound and cyanoacrylate in a ratio of 1 to 2 (hereinafter referred to as an ultraviolet absorber 2). The ultraviolet absorber 2 mixed in the display panel is mixed with polyethylene terephthalate in a ratio of 1:1. The film layer and the hard coating layer are stacked in the same manner as Example 1.

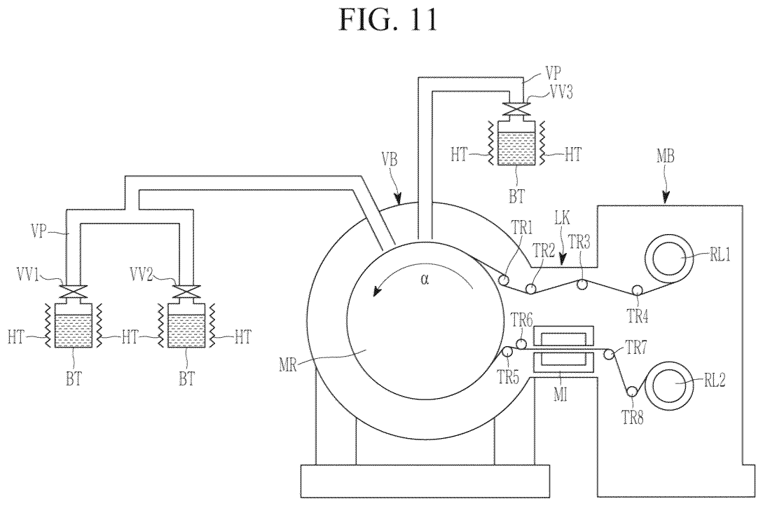

The manufacturing process of the low refractive index layer of the display panel will be described with reference to FIG. 11. FIG. 11 illustrates a manufacturing process of a low refractive index layer of the display panel shown in FIG. 5.

### Example 3

Except for the following, all conditions are carried out in the same manner as in Example 1.

The film uses polyethylene terephthalate, and the hard coating layer is applied and dried on the film layer.

Next, the ultraviolet absorber 2 is mixed. The mixed ultraviolet absorber 2 is put into a boat BT and heated with a heater HT.

R-type SQ is put into another boat BT and heat is applied with the heater HT.

When the film rotates over the main roller MR inside the vacuum bath VB and is put in, the first valve VV1, a second valve VV2, and the third valve VV3 are opened, allowing heated vaporizable material, heated ultraviolet absorber 2, and R-type SQ compound to be supplied into the vacuum bath VB in vapor form.

The microwave irradiation device MI generates plasma from the ultraviolet absorber 2 and R-type SQ to sputter on the film at a ratio of about 8 to about 2. The film formed through sputtering is deposited on the hard coating layer to have a thickness of about 100 nm. After film formation, the film is discharged to the main body MB along the tension seventh roller TR7 and the tension eighth roller TR8.

### Example 4

Except for the following, all conditions are carried out in the same manner as in Example 3.

The microwave irradiation device MI generates plasma from the ultraviolet absorber 1 and the R-type SQ to sputter on the film layer at a ratio of about 7 to about 3.

### Example 5

Except for the following, all conditions are carried out in the same manner as in Example 3.

The ultraviolet absorber 1 is mixed.

When the film rotates over the main roller MR inside the vacuum bath VB and is put in, the first valve VV1, the second valve VV2, and the third valve VV3 are opened, allowing heated vaporizable material, heated ultraviolet absorber 2, and R-type SQ compound to be supplied into the vacuum bath VB in vapor form.

The microwave irradiation device MI generates plasma from the ultraviolet absorber 2 and R-type SQ to sputter on the film at a ratio of about 8 to about 2.

### Comparative Example 1

Except for the following, all conditions are carried out in the same manner as in Example 1.

Polyethylene terephthalate is used during the film manufacturing process, and no ultraviolet absorbers are added.

### Comparative Example 2

Except for the following, all conditions are carried out in the same manner as in Comparative Example 1.

A sample of Experimental Example 1 was prepared in which a film was manufactured by adding an azomethine-based compound and benzotriazole to a film layer including polyethylene terephthalate in a ratio of about 1 to about 2.5.

### Comparative Example 3

Except for the following, all conditions are carried out in the same manner as in Comparative Example 3.

Comparative Example 3 includes a window including R-type SQ without the ultraviolet absorber 2.

### [Experimental Example 1] Transmission Spectral Spectrum and Reflection Spectral Spectrum

Samples of Example 1, Comparative Example 1, and Comparative Example 2 were prepared and put into a spectrophotometer (CM3700A), and the transmittance and reflectance at about 370 nm and about 400 nm were checked.

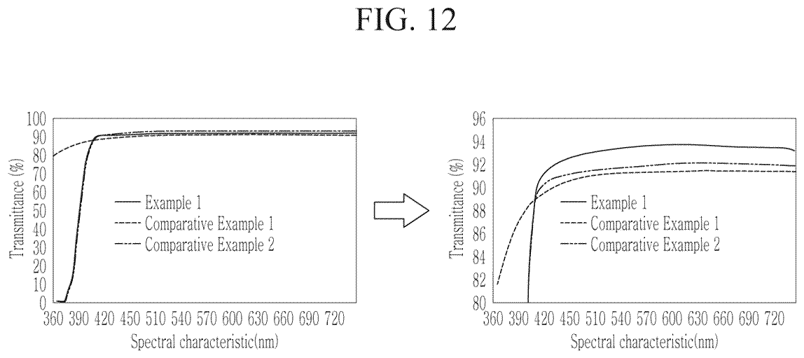

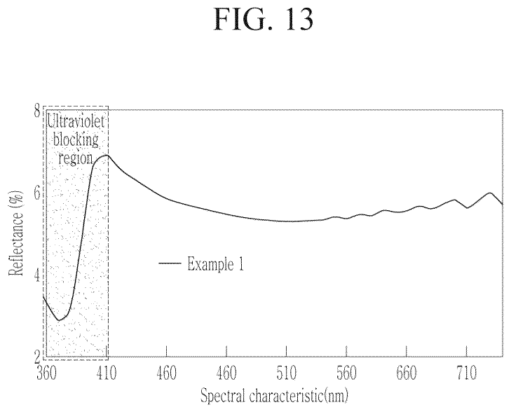

With reference to FIG. 12, FIG. 13, and Table 1, the transmittance and reflectance of Experimental Example 1, Comparative Example 1, and Comparative Example 2 in the ultraviolet region and visible ray region are described. FIG. 12 is a graph showing the results of the transmission spectral spectrum of the display panel shown in FIG. 4, and FIG. 13 is a graph showing the results of the reflection spectral spectrum of the display panel shown in FIG. 4. Table 1 shows the data used in the graph.

The left graph of FIG. 12 shows the spectral characteristics at the total transmittance, and the right graph shows the spectral characteristics at the transmittance of 80 to 100%.

Looking at the transmittance of ultraviolet and visible ray at a wavelength of 370 nm, Comparative Example 1 had transmittance of 85.01%, while Comparative Example 2 and Example 1 had transmittance of 0%. Looking at the transmittance of ultraviolet and visible ray at a wavelength of 400 nm, Comparative Example 1 had transmittance of 89.88%, while Comparative Example 2 had transmittance of 82.68% and Example 1 had transmittance of 83.18%.

In other words, it can be seen that when the ultraviolet absorber 1 is added to the film layer FLM in accordance with an embodiment of the present invention, the display device has the effect of blocking ultraviolet at a wavelength of 370 nm or less.

FIG. 13 shows the reflection spectral spectrum of Example 1 when the ion voltage is about 300 V. The reflectance of Example 1 was 1.34% at a wavelength of 370 nm and 7.6% at a wavelength of 400 nm.

From this experimental data, it can be seen that when the ultraviolet absorber 1 is added to the film layer FLM in accordance with an embodiment of the present invention, the window may serve an anti-reflection role at a wavelength of 370 nm or less.

TABLE 1

| Wavelength (nm) | 370 | 380 | 390 | 400 | 410 | 420 | 430 | 440 | 450 | 460 |
|---|---|---|---|---|---|---|---|---|---|---|
| Transmittance | 85.01 | 88.46 | 89.44 | 89.88 | 90.17 | 90.41 | 90.59 | 90.73 | 90.89 | 91.02 |
| of Comparative | | | | | | | | | | |
| Example 1 (%) | | | | | | | | | | |
| Transmittance | 0 | 13.48 | 52.83 | 82.68 | 89.57 | 90.38 | 90.71 | 90.9 | 91.07 | 91.18 |
| of Comparative | | | | | | | | | | |
| Example 2 (%) | | | | | | | | | | |
| Transmittance | 0 | 13.71 | 53.25 | 83.18 | 90.32 | 91.39 | 91.91 | 92.24 | 92.52 | 92.72 |
| of Experimental | | | | | | | | | | |
| Example 1 (%) | | | | | | | | | | |
| Reflectance of | 1.34 | 2.13 | 4.88 | 7.57 | 8.22 | 8.03 | 7.86 | 7.64 | 7.35 | 7.05 |
| Experimental | | | | | | | | | | |
| Example 1 (%) | | | | | | | | | | |
| Wavelength (nm) | 470 | 480 | 490 | 500 | 510 | 520 | 530 | 540 | 550 | — |
| Transmittance | 91.13 | 91.23 | 91.35 | 91.42 | 91.51 | 91.56 | 91.64 | 91.67 | 91.71 | — |
| of Comparative | | | | | | | | | | |
| Example 1 (%) | | | | | | | | | | |
| Transmittance | 91.26 | 91.35 | 91.44 | 91.5 | 91.56 | 91.61 | 91.65 | 91.67 | 91.71 | — |
| of Comparative | | | | | | | | | | |
| Example 2 (%) | | | | | | | | | | |
| Transmittance | 92.9 | 93.07 | 93.22 | 93.33 | 93.45 | 93.52 | 93.58 | 93.61 | 93.63 | — |
| of Experimental | | | | | | | | | | |
| Example 1 (%) | | | | | | | | | | |
| Reflectance of | 6.75 | 6.47 | 6.21 | 5.96 | 5.75 | 5.59 | 5.43 | 5.30 | 5.22 | — |
| Experimental | | | | | | | | | | |
| Example 1 (%) | | | | | | | | | | |

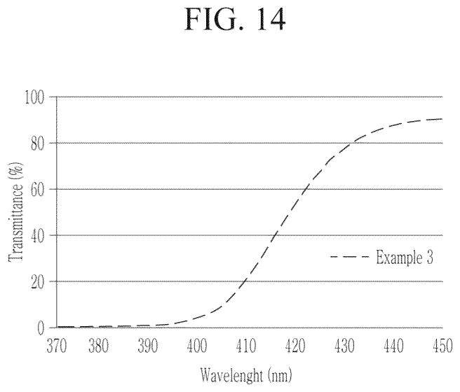

With reference to FIG. 14 and Table 2, the optical characteristics of Example 3 in the ultraviolet region and the visible ray region are described. FIG. 14 is a graph showing the results of ultraviolet and visible line spectral analysis of the display panel shown in FIG. 5, and Table 2 shows data on the reflection spectral spectrum. First, the transmittance of Example 3 is described with reference to FIG. 14. The window sample of Example 3 was prepared, and the transmittance was measured by using UV-Vis equipment.

The transmittance of Example 3 is about 30% or less in the ultraviolet absorption region of about 370 to about 410 nm, and in particular, the transmittance is about 5% or less in the wavelength band of about 405 nm or less.

Accordingly, it can be seen that when the ultraviolet absorber 2 is added to the low refractive index layer in accordance with an embodiment of the present invention, the display device has the effect of blocking ultraviolet at a wavelength of about 400 nm or less.

Next, referring to Table 2, it can be seen that the reflectance of Example 3 was 1.42% at a wavelength of 550 nm. Therefore, it can be seen that when the ultraviolet absorber 2 is added to the low refractive index layer in accordance with an embodiment of the present invention, the window may provide an anti-reflection role at a wavelength of about 550 nm or less.

TABLE 2

| Wavelength (nm) | 360 | 370 | 380 | 390 | 400 | 410 | 420 | 430 | 440 | 450 |
|---|---|---|---|---|---|---|---|---|---|---|
| Reflectance | 1.80 | 1.97 | 2.23 | 2.52 | 2.75 | 2.86 | 2.85 | 2.84 | 2.76 | 2.62 |
| of Example 3 | | | | | | | | | | |
| (%) | | | | | | | | | | |
| Wavelength (nm) | 460 | 470 | 480 | 490 | 500 | 510 | 520 | 530 | 540 | 550 |
| Reflectance | 2.48 | 2.33 | 2.19 | 2.06 | 1.91 | 1.78 | 1.65 | 1.55 | 1.48 | 1.42 |
| of Example 3 | | | | | | | | | | |
| (%) | | | | | | | | | | |

### Experimental Example 3

### Surface Characteristic Analysis Results

The characteristics related to the surface hardness of Example 3 will be described through Table 3.

Table 3 shows the initial surface contact angle measurement results. Referring to Table 3, it can be seen that the initial contact angle of Example 3 has a value of 110 degrees or more. Additionally, the contact angle is measured to be 95 degrees or more after 1 Kgf, 5 K in eraser chemical resistance.

TABLE 3

| Number of times/degrees (°) | First | Second | Third |
|---|---|---|---|
| Contact angle of Example 3 | 112.3 | 111.9 | 112.8 |

Accordingly, it can be seen that when the ultraviolet absorber 2 is added to the low refractive index layer in accordance with an embodiment of the present invention, the surface may have a hardness capable of preventing defects such as cracks from occurring in a window that is applied to a flexible display that is repeatedly folded and unfolded. Accordingly, it is possible to increase the reliability of the display device.

### Experimental Example 4

Surface Analysis Results Using x-Ray Photoelectron Spectroscopy

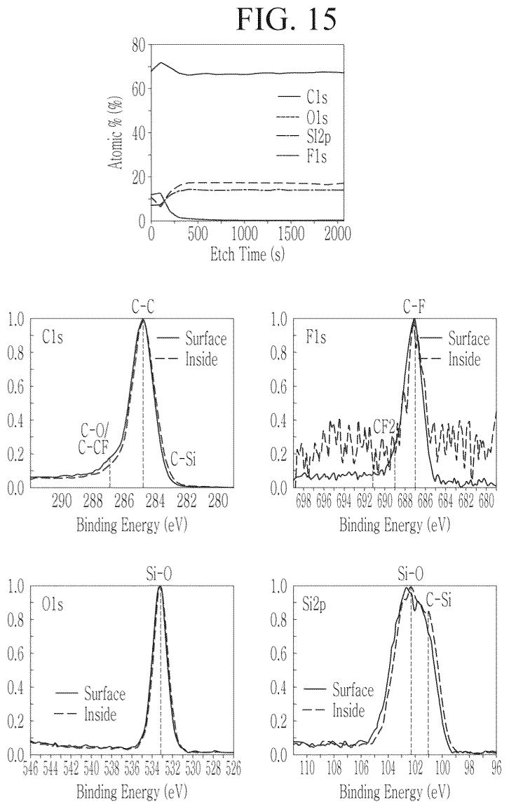

The surface characteristics of Example 3 are described through FIG. 15 and Table 4. FIG. 15 is a graph showing surface analysis results through x-ray photoelectron spectroscopy (XPS) of the display panel shown in FIG. 5, and Table 4 shows the data of the surface analysis results through the XPS.

Referring to Table 4 below, Example 3 has a fluorine (F) content of 0.68% inside the film, while Comparative Example 3 has a fluorine (F) content of 17.81%. In addition, Example 3 had an oxygen (O) content of 8.64% inside and outside the film, while Comparative Example 3 had an oxygen (O) content of 5.26%.

Thus, it can be seen that when the ultraviolet absorber 2 is added to the low refractive index layer in accordance with an embodiment of the present invention, the F content inside the film is reduced compared to the case where the ultraviolet absorber 2 is not added. In addition, it can be seen that the O content increases compared to the comparative example, which indicates that the Si—O bond increases.

TABLE 4

| Surface and interior | | C1s | F1s | O1s | | | | |
|---|---|---|---|---|---|---|---|---|
| composition (XPS) | | [%] | [%] | [%] | Si2p | C/Si | F/Si | O/Si |
| Example 1 | Surface | 71.91 | 14.18 | 6.67 | 7.23 | 9.95 | 1.96 | 0.92 |
| | Interior | 66.62 | 0.64 | 1.97 | 14.48 | 4.60 | 0.04 | 1.26 |
| Comparative | Surface | 76.51 | 20.60 | 2.89 | — | — | — | — |
| Example 3 | Interior | 79.82 | 17.81 | 2.37 | — | — | — | — |

Referring to FIG. 15, it can be seen that although C—F peaks on the surface of Example 5 on the XPS graph, the peak of CF2 is particularly high.

FIG. 16 is a block diagram illustrating an electronic device according to an embodiment of the present invention.

Referring to FIG. 16, in an embodiment of the present invention, an electronic device 900 may include a processor 910, a memory device 920, a storage device 930, an input/output (“I/O”) device 940, a power supply 950, and a display device 960. Here, the display device 960 may correspond to the display device 1000 as shown in for example FIGS. 1, 2 and 3. The electronic device 900 may further include a plurality of ports for communicating with a video card, a sound card, a memory card, a universal serial bus (“USB”) device, or the like. In an embodiment of the present invention, the electronic device 900 may be implemented as a television. In another embodiment of the present invention, the electronic device 900 may be implemented as a smart phone. However, embodiments of the present invention are not limited thereto, and in another embodiment of the present invention, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment of the present invention, the processor 910 may be a microprocessor, a central processing unit (“CPU”), an application processor (“AP”), or the like. The processor 910 may be coupled to other components via an address bus, a control bus, a data bus, or the like. In an embodiment of the present invention, the processor 910 may be coupled to an extended bus such as a peripheral component interconnection (“PCI”) bus.

The memory device 920 may store data for operations of the electronic device 900. In an embodiment of the present invention, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment of the present invention, the storage device 930 may include a solid state drive (“SSD”) device, a hard disk drive (“HDD”) device, a CD-ROM device, or the like. In an embodiment of the present invention, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment of the present invention, the display device 960 may be included in the I/O device 940.

While the present invention has been described with reference to exemplary embodiments thereof, it will be understood by those of ordinary skill in the art that various changes in form and details may be made thereto without departing from the spirit and scope of the present invention.

### DESCRIPTION OF SYMBOLS

U-FLM: Film layer including absorber
U-LR: Low refractive index layer including absorber
FLM: Film layer
HC: Hard coating layer
LR: Low refractive index layer
CW: Cover Window
1000: Display device
ENC: Encapsulation layer

What is claimed is:

1. A display device, comprising:
a substrate;
a display layer disposed on the substrate;
a film layer disposed on the display layer;
a hard coating layer disposed on the film layer; and
a low refractive index layer disposed on the hard coating layer,
wherein the film layer includes an ultraviolet absorber.

2. The display device of claim 1, wherein
the low refractive index layer includes dodecafluoroheptyl acrylate.

3. The display device of claim 2, wherein
the ultraviolet absorber includes at least one of an azomethine-based compound, cyanoacrylate, or benzotriazole.

4. The display device of claim 3, wherein
the low refractive index layer has a thickness between about 80 nm and about 120 nm.

5. The display device of claim 4, wherein
the film layer includes polyethylene terephthalate.

6. The display device of claim 5, wherein
the ultraviolet absorber includes a mixture of an azomethine-based compound and benzotriazole in a ratio of about 0.8 to about 1.2 for the azomethine-based compound to about 2 to about 3 for the benzotriazole.

7. The display device of claim 6, wherein
the film layer includes a mixture of the polyethylene terephthalate, and the mixture of an azomethine-based compound and benzotriazole in the ratio of about 0.8 to about 1.2 for the azomethine-based compound to about 2 to about 3 for the benzotriazole.

8. The display device of claim 5, wherein
the ultraviolet absorber includes a mixture of an azomethine-based compound and cyanoacrylate in a ratio of about 0.8 to about 1.2 for the azomethine-based compound to about 1.6 to about 2.4 for the cyanoacrylate.

9. The display device of claim 8, wherein
the film layer includes polyethylene terephthalate,
the film layer includes a mixture of the polyethylene terephthalate, and mixture of an azomethine-based compound and cyanoacrylate in a ratio of about 0.8 to about 1.2 for the azomethine-based compound to about 1.6 to about 2.4 for the cyanoacrylate.

10. A display device, comprising:
a substrate;
a display layer disposed on the substrate;
a film layer disposed on the display layer;
a hard coating layer disposed on the film layer; and
a low refractive index layer disposed on the film layer,
wherein the low refractive index layer includes an ultraviolet absorber.

11. The display device of claim 10, wherein
the low refractive index layer has a thickness between about 80 nm and about 120 nm.

12. The display device of claim 10, wherein
the low refractive index layer includes random silsesquioxane monomers to which 12 perfluorinated groups and 6 reactive groups are attached.

13. The display device of claim 12, wherein
each of the 12 perfluorinated groups is selected from at least one of C₃F₇, C₃F₉, C₄F₉, or CsF₁₁.

14. The display device of claim 12, wherein
the ultraviolet absorber includes at least one compound of an azomethine-based compound, cyanoacrylate, or benzotriazole.

15. The display device of claim 14, wherein
the ultraviolet absorber includes a mixture of an azomethine-based compound and cyanoacrylate in a ratio of about 0.8 to about 1.2 for the azomethine-based compound to about 1.6 to about 2.4 for the cyanoacrylate.

16. The display device of claim 15, further comprising
a mixture of silsesquioxane monomers and the ultraviolet absorber in a ratio of about 5.4 to about 9.6 for the silsesquioxane monomers to about 1.6 to about 2.4 for the ultraviolet absorber.

17. The display device of claim 14, wherein
the ultraviolet absorber includes a mixture of an azomethine-based compound and benzotriazole in a ratio of about 0.8 to about 1.2 for the azomethine-based compound to about 2 to about 3 for the benzotriazole.

18. The display device of claim 17, wherein
a mixture of the silsesquioxane monomers and the ultraviolet absorber in a ratio of about 5.4 to about 9.6 for the silsesquioxane monomers to about 1.6 to about 2.4 for the ultraviolet absorber.

19. An electronic device comprising:
a display device; and
a power supply configured to provide power to the display device,
wherein the display device comprises:
a substrate;
a display layer disposed on the substrate;
a film layer disposed on the display layer;
a hard coating layer disposed on the film layer; and
a low refractive index layer disposed on the hard coating layer,
wherein the film layer or the low refractive index layer includes an ultraviolet absorber.

20. The electronic device of claim 19, wherein
the ultraviolet absorber includes at least one of an azomethine-based compound, cyanoacrylate, or benzotriazole.
